(19) United States
(12) Patent Application Publication
(10) Pub. No.: US 2020/0232933 A1
(43) Pub. Date: Jul. 23, 2020

(54) PATTERNING DEVICE, MANUFACTURING METHOD FOR A PATTERNING DEVICE, SYSTEM FOR PATTERNING A RETICLE, CALIBRATION METHOD OF AN INSPECTION TOOL, AND LITHOGRAPHIC APPARATUS

(71) Applicant: ASML NETHERLANDS B.V., Veldhoven (NL)

(72) Inventors: Thomas Leo Maria HOOGENBOOM, Breda (NL); Hugo Augustinus Joseph CRAMER, Eindhoven (NL)

(73) Assignee: ASML NETHERLANDS B.V., Veldhoven (NL)

(21) Appl. No.: 16/642,402

(22) PCT Filed: Aug. 9, 2018
(86) PCT No.: PCT/EP2018/071682

§ 371 Date: Feb. 27, 2020

(30) Foreign Application Priority Data
Sep. 26, 2017 (EP) 17193045.6
Jun. 25, 2018 (EP) 18179618.6

(51) Int. Cl. G01N 21/93; G01N 21/956; G03F 7/20

(52) U.S. Cl. CPC G01N 21/93; G01N 21/956; G03F 7/70516; G03F 7/70641; G03F 7/70866; G03F 7/70625

(57) ABSTRACT

A method for manufacturing or adjusting a reticle having a predetermined functionality, the method including obtaining a reticle having a first pattern, the first pattern representing a first functionality of structures provided to a substrate using the reticle, and patterning the reticle having the first pattern with a second pattern using a pattern generating tool, the combined first and second patterns having the predetermined functionality.

### CROSS-REFERENCE TO RELATED APPLICATIONS

This application claims priority of EP application 17193045.6 which was filed on Sep. 26, 2017 and EP application 18179618.6 which was filed on Jun. 25, 2018 which are incorporated herein in its entirety by reference

### BACKGROUND

### Field of the Invention

The present invention relates to a manufacturing process for a patterning device, also referred to as a reticle, as can e.g. be applied in a lithographic projection apparatus.

### Description of the Related Art

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern, or part of a circuit pattern, that is to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

Patterning devices or reticles are typically manufactured by writing a desired pattern on a blank provided with a photoresist, e.g. using an electron beam (e-beam) or a laser. Such a process may take a substantial amount of time. In addition, once the patterning device or reticle has been manufactured, it may be difficult to make adjustments to the pattern.

In order to verify the accuracy of processing steps performed on substrates, e.g. processing steps performed by lithographic apparatuses, inspection tools are often used to inspect structures or targets that have been patterned. Based on such an inspection, feedback loops may be implemented to compensate for occurring drifts in any applied lithographic process parameter. Inspection methods as performed by such tools may however be affected by noise or interference, thus adversely affecting the accuracy of the measurements and affecting the possibility to using the measurements as input for any feedback to the lithographic apparatus. It is therefore desirable to increase the accuracy of measurements as performed by inspection tools used in manufacturing processes of semiconductor devices.

### SUMMARY

It is desirable to provide a more flexible manufacturing method for patterning devices or reticles. According to an embodiment of the present invention, there is provided a manufacturing process for a reticle having a predetermined functionality, the manufacturing method comprising:
obtaining a reticle having a first pattern, the first pattern representing a first functionality of an integrated circuit;
patterning the reticle having the first pattern with a second pattern using a pattern generating tool, the combined first and second pattern having the predetermined functionality.

According to an embodiment of the present invention, there is provided a manufacturing method for a reticle, the manufacturing method comprising:
providing a reticle to a first pattern generating tool;
patterning the reticle with a first pattern;
providing the reticle having the first pattern to a second pattern generating tool;
patterning the reticle with a second pattern configured to form a combined pattern with the first pattern, wherein the combined pattern has a different functionality than the first pattern.

According to an embodiment of the invention, there is provided a system for patterning a reticle with a pattern, the system comprising:
a first pattern generating tool configured to pattern the reticle with a first pattern;
a second pattern generation tool for patterning the reticle with a second pattern, whereby the combined first and second pattern forms a pattern having a desired functionality.

According to a further embodiment of the invention, there is provided a lithographic apparatus comprising:

a pattern generation tool configured to:
receive a reticle having a first pattern, the first pattern representing a first functionality of an integrated circuit;
patterning the reticle with a second pattern configured to form a combined pattern with the first pattern, wherein the combined pattern has a predetermined functionality; an illumination system configured to condition a radiation beam;
   a support constructed to support the reticle, the reticle being capable of imparting the radiation beam with a pattern in its cross-section to form a patterned radiation beam;
   a substrate table constructed to hold a substrate; and
   a projection system configured to project the patterned radiation beam onto a target portion of the substrate.

It is desirable to improve the accuracy at which inspection tools can determine lithographic process parameters.

According to a further aspect of the present invention, there is provided a calibration method of an inspection tool, the calibration method comprising determining a calibration parameter of the inspection tool by:
receiving data associated with one or more substrates comprising a plurality of target portions onto which a respective plurality of patterns is provided, whereby the plurality of patterns are formed by a lithographic process characterized by a known variation of at least one process parameter with respect to a nominal value;
determining a characteristic of each of the plurality of patterns based on the received data; and
determining the calibration parameter of the inspection tool, based on the measured characteristics and the known process parameter variation.

According to yet a further aspect of the invention, there is provided a method of determining a characteristic of a pattern, the method comprising:
receiving data associated with one or more substrates comprising a plurality of target portions onto which a respective plurality of patterns is provided, whereby the plurality of patterns are formed by a lithographic process characterized by a known variation of at least one process parameter with respect to a nominal value;
determining a measurement set comprising a plurality of measured characteristics of the respective plurality of patterns from that data;
filtering the measurement set based on the known process parameter variation.

According to yet a further aspect of the invention, there is provided an inspection method of determining a characteristic of a pattern, the method comprising:
receiving one or more substrates comprising a plurality of target portions onto which a respective plurality of patterns is provided, whereby the plurality of patterns are formed by a lithographic process characterized by a known variation of at least one process parameter with respect to a nominal value;
obtaining a measurement set comprising a plurality of measured characteristics of the respective plurality of patterns using an inspection tool;
filtering the measurement set based on the known process parameter variation.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 schematically depicts a patterning device including a patterned area.

FIG. 3 schematically depicts a flow-chart of a manufacturing method according to the present invention;

FIGS. 4 and 5 schematically depict patterning devices, according to the present invention, as can be obtained using a method according to the present invention.

FIG. 6 schematically depicts the patterning of a feature in two distinct patterning steps.

FIG. 7 schematically depicts a flowchart of a method according to the present invention.

FIG. 8 schematically depicts the application of a process parameter variation on a plurality of patterns.

FIG. 9 schematically depicts a flowchart of a calibration method according to the present invention.

### DETAILED DESCRIPTION

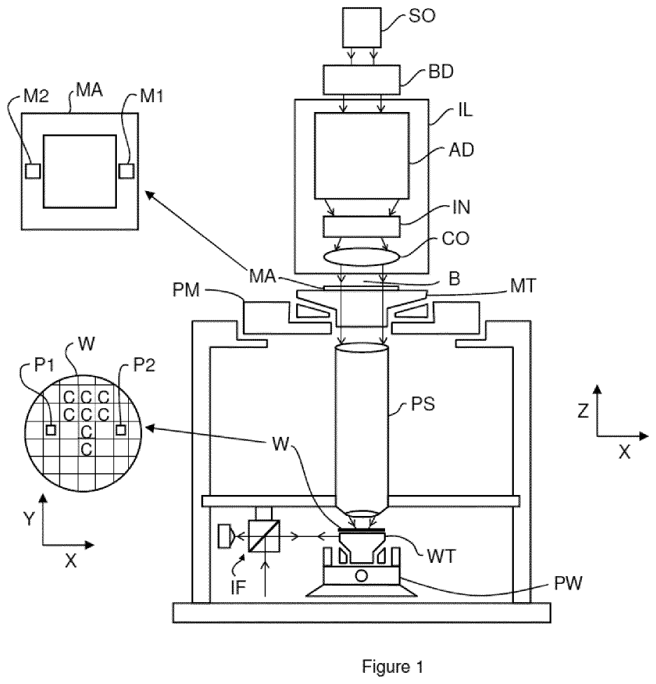

FIG. 1 schematically depicts a lithographic apparatus according to one embodiment of the invention. The apparatus includes an illumination system (illuminator) IL configured to condition a radiation beam B (e.g. UV radiation or any other suitable radiation), a mask support structure (e.g. a mask table) MT constructed to support a patterning device (e.g. a mask) MA and connected to a first positioning device PM configured to accurately position the patterning device in accordance to certain parameters. The apparatus also includes a substrate table (e.g. a wafer table) WT or “substrate support” constructed to hold a substrate (e.g. a resist-coated wafer) W and connected to a second positioning device PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies, or a part of one or more dies) of the substrate W.

The illumination system may include various types of optical components, such as refractive, reflective, magnetic, electromagnetic, electrostatic or other types of optical components, or any combination thereof, for directing, shaping, or controlling radiation.

The mask support structure supports, i.e. bears the weight of, the patterning device. In an embodiment, the patterning device can e.g. a patterning device according to the present invention. It holds the patterning device in a manner that depends on the orientation of the patterning device, the design of the lithographic apparatus, and other conditions, such as for example whether or not the patterning device is held in a vacuum environment. The mask support structure can use mechanical, vacuum, electrostatic or other clamping techniques to hold the patterning device. The mask support structure may be a frame or a table, for example, which may be fixed or movable as required. The mask support structure may ensure that the patterning device is at a desired position, for example with respect to the projection system. Any use of the terms “reticle” or “mask” herein may be considered synonymous with the more general term “patterning device”.

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Masks are well known in lithography, and include mask types such as binary, alternating phase-shift, and attenuated phase-shift, as well as various hybrid mask types. Patterning devices that are transmissive may e.g. be used in combination with an illumination system IL that applies a UV or DUV radiation source (e.g. having a wavelength of or about 365, 248, 193, 157 or 126 nm). Patterning devices that are reflective may e.g. be used in combination with an illumination system that applies an EUV radiation source, e.g. having a wavelength of about 10-13 nm.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a reflective mask).

The lithographic apparatus may be of a type having two (dual stage) or more substrate tables or “substrate supports” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the mask support structure (e.g., mask table MT), and is patterned by the patterning device. Having traversed the mask MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioning device PM. Similarly, movement of the substrate table WT or “substrate support” may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT or “mask support” and the substrate table WT or “substrate support” are kept essentially stationary, while an entire pattern imparted to the radiation beam is projected onto a target portion C at one time (i.e. a single static exposure). The substrate table WT or “substrate support” is then shifted in the X and/or Y direction so that a different target portion C can be exposed. In step mode, the maximum size of the exposure field limits the size of the target portion C imaged in a single static exposure.

2. In scan mode, the mask table MT or “mask support” and the substrate table WT or “substrate support” are scanned synchronously while a pattern imparted to the radiation beam is projected onto a target portion C (i.e. a single dynamic exposure). The velocity and direction of the substrate table WT or “substrate support” relative to the mask table MT or “mask support” may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

Combinations and/or variations on the above described modes of use or entirely different modes of use may also be employed.

According to an aspect of the present invention, there is provided a manufacturing method for a reticle for use in a lithographic apparatus. A reticle or patterning device as used in a lithographic apparatus typically has a rectangular shape and comprises an area that is patterned, i.e. provided with a pattern.

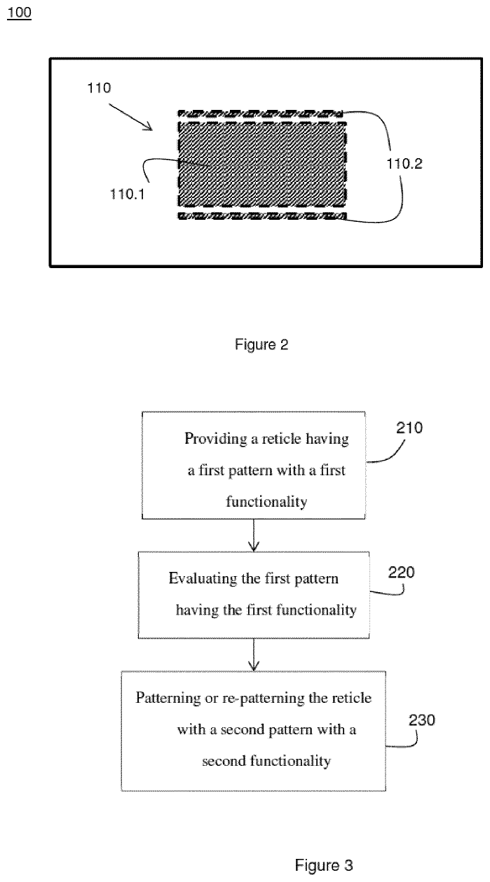

FIG. 2 schematically shows a top view of a reticle 100 including a pattered area 110. In the arrangement as shown, the patterned area 110 includes a pattern 110.1 that is to be imparted to the radiation beam applied so as to form, during an exposure process, a pattern on a substrate. The pattern as formed on the substrate will serve to manufacture part of an integrated circuit (IC) on the substrate. The pattern 110.1 is further on also referred to as the IC-pattern. The patterned area 110 also includes a border or border area 110.2 in which a plurality of different types of marks may be provided, e.g. including alignment marks, overlay marks, metrology marks; these may e.g. facilitate assessing the accuracy of the projection and exposure process and/or may facilitate the projection or exposure process itself. The pattern or patterns in the border area will typically not be part of the exposed pattern forming the integrated circuit on the substrate. Note that marks for facilitating the exposure process, such as alignment marks, or marks for evaluating the accuracy of the exposure process, such as overlay marks, may also be provided along other sides of the pattern 110.1. Alternatively, or in addition, such markings may also be provided in internal scribe lanes, e.g. inside the 110.1 pattern.

Such a reticle 100 may be manufactured by a number of techniques, e.g. depending on the method of writing a pattern onto the reticle. Typically, an e-beam or a laser are currently applied for writing a pattern onto a reticle. The process of manufacturing a reticle including a pattern may e.g. comprise the following steps:
providing a glass or quartz plate;
depositing a Cr-layer or the like on the glass or quartz plate;
depositing an anti-reflective coating (ARC) on the Cr-layer;
applying a photoresist layer on the ARC;
direct writing a desired pattern on the photoresist layer;
developing the pattern in the photoresist layer;
etching the pattern into the Cr-layer and
removing the photoresist layer.

In case the reticle is to be used with an EUV-type radiation beam, the manufacturing process may e.g. include the following steps:
providing a low thermal expansion (LTE) substrate;
depositing a multilayer stack on the substrate;
depositing a capping layer on the multilayer stack and a buffer layer on the capping layer;
depositing an absorber layer on the buffer layer;
applying a photoresist layer on the absorber layer;
direct writing a desired pattern on the photoresist layer;
developing the pattern in the photoresist layer;
etching the pattern into the absorber layer and removing the photoresist layer.

Using these processes, a patterning device 100 having a pattern 110 as schematically shown in FIG. 2 may be generated.

Typically, from then on, the functionality of the pattern 110 will not be altered; the desired pattern, having a predetermined desired functionality, will typically be written on the photoresist in one process step, e.g. a direct writing step.

It is believed that this approach poses some drawbacks and may be improved. The alternative manner of manufacturing a patterning device that is proposed in an embodiment of the present invention involves the manufacturing of a patterning device such as a reticle in two distinct patterning steps to arrive at a desired pattern.

The use of two distinct patterning steps significantly increases the flexibility with which a pattern can be generated, and offers the possibility to arrive, in an efficient way, at a desired pattern. Such a flexibility may e.g. enable the exposure of a lot of substrates with a particular pattern, or even the exposure of a single substrate with a particular pattern. In an embodiment of the present invention, the manufacturing process of a reticle thus enables to modify a desired pattern on a per lot basis, on a per substrate basis, or even on a per die basis. As an example of the latter, the present invention can e.g. be used to inscribe a unique digital code or signature in each IC that is manufactured, e.g. enabling each IC to be traced. This may e.g. be useful to trace the origin of air-bag ignition chip failures.

Embodiments of the present invention may e.g. include manufacturing processes whereby different tool or different types of tools may be applied to perform the two distinct patterning steps. Embodiments of the present invention may also include manufacturing processes whereby an evaluation step is performed in between the two distinct patterning steps.

As an example of such an evaluation step, a process set-up of a lithographic apparatus, during which the patterning device having the first pattern is used, can be mentioned. The purpose of such a process set-up can be understood as follows:

The objective or purpose of a reticle is to impart a radiation beam with a pattern that needs to be aligned with a target area on a substrate, e.g. an area comprising a previously exposed pattern or a plurality of previously exposed patterns. In order to obtain an accurate transfer of the patterned radiation beam, the various components of the lithographic apparatus may need to be configured, calibrated or tuned to arrive at the best possible transfer of the pattern. This process of adjusting the lithographic apparatus may e.g. be referred to as a process to set-up the apparatus.

During such a set-up of the apparatus, one may occasionally encounter the situation that certain patterns or portions of patterns are not optimal, given the particular set-up of the lithographic apparatus.

In particular, it is worth mentioning that the patterning of a properly set-up lithographic apparatus may still be non-optimal:
The lithographic apparatus may drift over time; either in a predictable way or in a way that can be measured and therefore compensated for in a feedback loop.
The substrate that is being patterned may change shape; either in a predictable way (e.g. because of heating effects), or in a way that can be measured, e.g. just before or during patterning. Such expected substrate shape variations can e.g. be compensated by adapting the patterning process, e.g. by adapting the pattering device.
The patterning device or reticle itself may be subject to drift in any of its properties, just because of time, or because it is being used for patterning (e.g. due to heating effects). If these changes are predictable, or can be modeled based on measurements, they can be compensated for.
The lithographic apparatus is also used to compensate for patterning imperfections that have developed on a substrate due to prior process steps, or that are predicted to occur in later process steps. Since the steps and apparatus used for substrate patterning are not necessarily the same for every substrate, even if the substrates are manufactured to essentially the same design, the compensation referred to above can also be different for each substrate being patterned.
As such, during the set-up of the lithographic apparatus, it may become clear that certain properties of marks or markings as applied on the reticle, e.g. alignment marks or overlay marks provided in the border or border area 110.2 of the pattern 110, are not ideal.

When such an assessment is made, the manufacturing process according to an embodiment of the present invention enables, by means of performing a second patterning step, to obtain a patterning device having the desired pattern, e.g. including marks having the desired dimensions. As another example, by means of performing a second patterning step, a changed or augmented pattern may be obtained, the pattern being changed or augmented in one of its physical dimensions, including but not restricted to size, shape, index of refraction, coefficient of extension, physical composition, etc., such that the desired changes in the patterning of a substrate are achieved.

More explicitly, the manufacturing process according to this embodiment may thus comprises the steps of:
obtaining a substrate having a first pattern, the first pattern representing a first functionality;
performing a process set up of a lithographic apparatus using the substrate;
determining a desired characteristic of the patterning device, e.g. based on the process set up, or on an expected drift characteristic or a required correction or compensation of patterning imperfections of previous process steps;
determining the second pattern based on desired characteristic.
patterning the substrate having the first pattern with a second pattern using a pattern generating tool, the combined first and second pattern having the desired functionality.

In such embodiment, the first pattern may e.g. comprise a first portion representative of the pattern that is to be projected into a resist layer of a substrate, this pattern having a particular functionality in the integrated circuit that is manufactured, and a second portion, e.g. comprising a plurality of alignment marks having different dimensions and/or pitches. This second portion thus having a particular functionality with respect to facilitating or assessing the exposure process.

A reticle having such a first pattern may e.g. be used in process set-up of a lithographic apparatus, during which set-up, it becomes apparent that a particular alignment mark of the plurality of alignment marks provided on the second portion enables the most accurate alignment.

In such case, the second pattern that is patterned onto the reticle may e.g. comprise a plurality of said particular alignment marks so as to arrive at a reticle comprising a reticle having a plurality of optimal alignment marks. Depending on the circumstances, it may also be possible that the second pattern results in a modification of some of the alignment marks, thereby resulting in marks having the optimal properties. The application of the second pattern could therefore also be described as a re-pattering step.

FIG. 3 schematically illustrates the above described process. The manufacturing process according to an embodiment of the present invention as illustrated in FIG. 3 comprises a first step 210 of providing a substrate having a first pattern with a first functionality. Subsequently, the process comprises the step 220 of evaluating the first pattern. Such an evaluation may e.g. take place during a process set up of a lithographic apparatus that will use the reticle. Based on the outcome of the evaluation, the manufacturing process then comprises a third step 230 of patterning or re-pattering at least part of the reticle with a second pattern, the second pattern having a second functionality, different from the first functionality.

The manufacturing method according to the present invention, which provides in a method of manufacturing a patterning device in two distinct patterning steps to arrive at a desired pattern may further advantageously be applied in other circumstances that illustrated above.

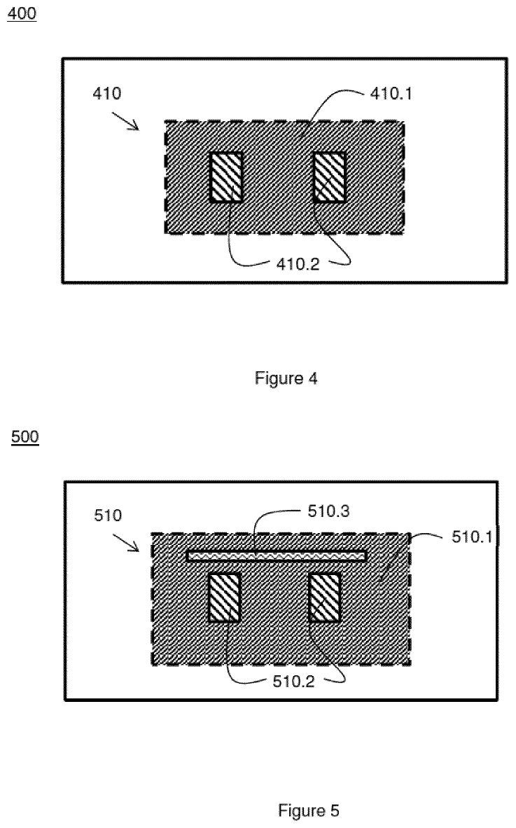

As a next example of a manufacturing method according to the present invention whereby two distinct patterning steps are applied, a method is discussed whereby the IC-pattern 110.1 of a desired pattern on a reticle is considered to be subdivided into two patterns, whereby each of those patterns is patterned separately in a distinct patterning step; the sequential performing of the distinct patterning steps resulting in the desired IC-pattern. In such embodiment, a purposive subdivision of a desired pattern, such as IC-pattern 110.1 shown in FIG. 2 is made beforehand. FIG. 4 schematically illustrates a patterning device or reticle 400 having a pattern 410 that is to be imparted to a radiation beam applied so as to form, during an exposure process, a pattern on a substrate; said pattern subsequently being used to manufacture a part of an integrated circuit (IC). As shown, the pattern 410 is subdivided into a first pattern 410.1 and a second pattern 410.2. In the embodiment as shown, the second pattern 410.2 form only a comparatively small portion of the combined desired pattern 410, i.e. the combined pattern having a desired functionality. In an embodiment, the second pattern may e.g. cover less than 10% of the desired pattern 410, e.g. less than 5% or only a few % of the area of the desired pattern 410. In accordance with an embodiment of the present invention, the desired pattern 410 may be patterned onto the patterning device by performing the steps of:
providing the reticle onto which the pattern 410 is to be provided to a first pattern generating tool and patterning the reticle with the first pattern 410.1 by the first pattern generating tool;
providing the reticle having the first pattern to a second pattern generating tool;
patterning the reticle with the second pattern 410.2 so as to arrive at a combined pattern comprising the first and second pattern 410.1, 410.2, the combined pattern having the desired functionality.

As will be clear to the skilled person, by subdividing the desired pattern 410 into two patterns 410.1, 410.2, neither one of these patterns, taken alone, will have the desired functionality of the combined pattern 410. Only when both patterns have been applied to the reticle, the desired functionality will be realized.

It has been devised by the inventors that there may be various reasons for subdividing a pattern such as an IC-pattern 110.1 or 410 into two pattern 410.1, 410.2 who, when combined, form a desired pattern.

In accordance with an embodiment of the present invention, a subdivision of a desired pattern or desired IC-pattern is based on a distribution of the pattern density of the pattern. In such embodiment, portions of the desired pattern having a low pattern density may be grouped so as to form a first pattern, whereas portions of the desired pattern having a high pattern density may be grouped so as to form a second pattern.

Within the meaning of the present invention, pattern density may be considered a measure to indicate the number or amount of distinct features per unit area. As such, areas having comparatively large or coarse features may be considered areas having a comparatively low pattern density, whereas areas have comparatively small, fine features may be considered areas having a comparatively high pattern density. In case such a subdivision is made, one may subsequently select which tools would be most suited for patterning the respective first pattern 410.1 and second pattern 410.2. It may e.g. be feasible to pattern the first pattern, e.g. the pattern comprising the comparatively coarse or large features, with a patterning tool that would be unsuited to pattern areas with a high pattern density. At the same time, it would be inefficient to use a tool that is suited to pattern patterns with a high pattern density for the patterning of large or coarse features.

It can be noted that the subdivision into a first pattern having coarse features and a second pattern having fine features does not require that both patterns need to occupy distinct areas as indicated in FIG. 4.

Both patterns may be interleaved or intertwined. In fact, one may even, on a feature by feature basis, determine whether or not a feature belongs to the first pattern, e.g. to be patterned by a first patterning tool or belongs to the second pattern, e.g. to be patterned by a second patterning tool. As an example of such a subdivision, the first pattern may e.g. consist of the main features that characterize the pattern as is should be patterned onto a substrate, whereas the second pattern e.g. consists of assist features to ensure the proper projection of the main features onto the substrate.

In another embodiment of the present invention, the subdivision of a desired IC pattern is based on the required functionality rather than on the feature or pattern density. In particular, the present invention enables an efficient manner to customize a reticle pattern; in an embodiment of the present invention, the pattern that is to be provided on the reticle is subdivided into a first pattern, referred to as a basic or generic IC pattern, and a second pattern, referred to as a specific or customer specific pattern. It may occur that a foundry, i.e. a chip or IC manufacturer, wishes to pattern different devices or layers forming parts of devices, whereby the applied pattern of the different devices or layers share a common design. It may even occur that the desired pattern for the different devices or layer is identical, apart from some or a few details. As an example, the detailed wiring of an FPGA array may be consider a detail, different from the common FPGA design. When such a subdivision is made, one may, in a first patterning step of a manufacturing process according to an embodiment of the present invention, a plurality of reticles is prepared by providing them with the first pattern. Subsequently, when a customer orders a particular reticle, one may complete the pattern on the reticles by a second patterning step whereby a second pattern, as specified by the customer, is applied.

As an example of such a specific or customer specific pattern, a pattern defining a position or positions of contact holes may be mentioned. In such an embodiment, the first pattern may comprise a plurality of possible positions of such contact holes, whereby the second pattern, based on a customer specification, provided in the actual contact hole pattern. Since the reticle with the first, basic or generic, pattern is already available, the manufacturing process from order to delivery of the customized reticle can be shortened. In addition, the manufacturing costs for such a customized reticle may be reduced.

As such, in an embodiment of the present invention, the second patterning step, which can also be referred to as a re-patterning step, could include applying modifications to any of the features that are patterned by the first patterning step. Such modifications can be made to any feature (coarse or fine), patterned during the first patterning step. In this respect, it can be noted that small changes at reticle level can create big changes in the patterning of the substrate—an effect that can be exploited to reduce the percentage of the patterning device that needs to be patterned. As such, in an embodiment, the re-patterning of the patterning device may e.g. be limited to the modification of only a few features on the patterning device. Even a modification on only a limited number of features by means of the second patterning step may lead to larger-scale (but controlled) changes in the pattern exposed on the substrate.

In an embodiment of the present invention, the aforementioned methods of:
subdividing a desired pattern into a pattern having a comparatively high pattern density and a pattern having a comparatively low pattern density, and
subdividing a desired pattern into a basis or generic pattern and a specific or customer specific pattern, may be combined.

FIG. 5 schematically shows an embodiment of a reticle or patterning device 500 in which both subdivisions are combined.

The reticle 500 as shown in FIG. 5 comprises a pattern 510, whereby the pattern 510 comprises three different patterns 510.1, 510.2 and 510.3.

In an embodiment, the combined patterns 510.1 and 510.2 may e.g. form a basic or generic pattern, whereas the pattern 510.3 may from a specific or customer specific pattern. Further, in the embodiment as illustrated, pattern 510.1 may e.g. have a comparatively low pattern density while the pattern 510.2 may e.g. have a comparatively high pattern density.

When such a subdivision of the pattern 510 is made, the pattern may e.g. be manufactured in the following manner:
providing the reticle onto which the pattern 510 is to be provided to a first pattern generating tool and patterning the reticle with the first pattern 510.1 by the first pattern generating tool;
providing the reticle having the first pattern to a second pattern generating tool;
patterning the reticle with the second pattern 510.2 so as to arrive at a combined pattern comprising the first and second pattern 510.1, 510.2, the combined pattern forming the basis or generic pattern of the reticle 510;
patterning the reticle with the third pattern 510.3, the third pattern 510.3 e.g. being based on a user specification.

In an embodiment of the present invention, the pattern as applied in the second patterning step is a volatile or removable pattern. Within the meaning of the present invention, a volatile or removable pattern refers to a pattern that either gradually disappears, e.g. by evaporation or which can be easily removed, e.g. using plasma-cleaning using radicals.

Patterns that possess such a property, i.e. pattern that are volatile or easily removable may e.g. be provided on the reticle using an electron beam induced deposition (EBID) tool. Electron beam-induced deposition (EBID) is a high-resolution direct write lithography technique that is capable of writing nanometer-scale patterns. In such a tool, an electron beam is focused onto a sample in a scanning electron microscope (SEM) and made to react with a gas, referred to as the precursor gas that is let into the SEM through a nozzle that is positioned near the reticle that is to be patterned. Due to the interaction with the e-beam, the gas molecules are dissociated into a volatile part, which can be removed out of the SEM, and a nonvolatile part, which remains on the reticle surface, forming a deposit. Typical precursors are W(CO)₆ and trimethyl (methylcyclopentadienyl)-platinum (IV) (MeCpPtMe₃), which lead to tungsten and platinum deposits, respectively. By appropriate selection of the precursor gas, a deposit can be obtained which is volatile or is easily removable, e.g. by means of plasma-cleaning using radicals.

The manufacturing method according to the present invention, which includes two distinct patterning steps to arrive at a patterning device with a desired pattern, can as discussed above, be used in various circumstances and for various purposes.

One of the merits of the present invention, is that it enables to incorporate the use of a patterning tool with limited patterning speed in the manufacturing process of patterning devices without substantially affecting the manufacturing time. The patterning tool with limited patterning speed may e.g. be applied to only pattern a comparatively small portion of the desired pattern, e.g. to adjust a previously applied first pattern. Such a comparatively small portion may e.g. represent a customer specific portion of the pattern.

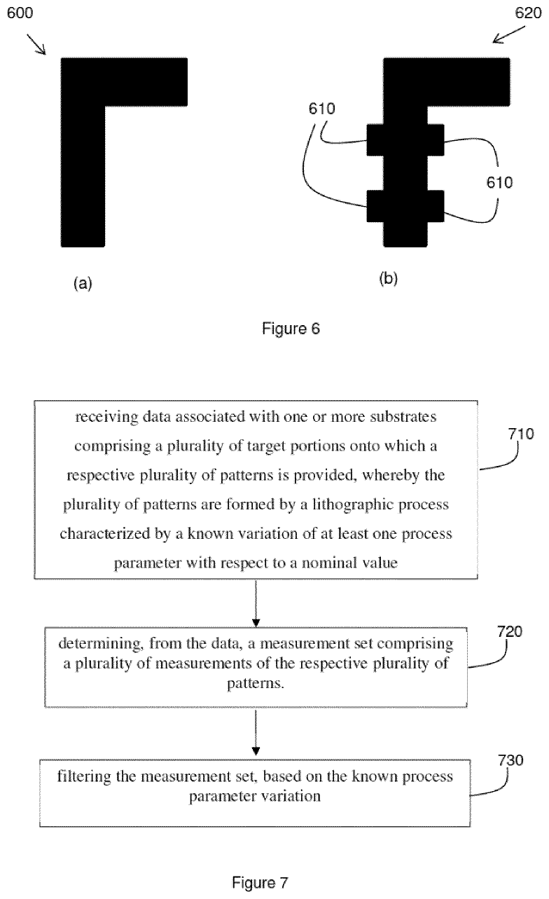

FIG. 6 schematically shows an example of a feature 600 as e.g. provided on a patterning device using a first patterning step (a). Using a second patterning step, the feature 600 may be complemented with a second pattern including features 610, to arrived at a desired combined pattern or feature 620.

Examples may e.g. include:
A variation of the circuit pattern (e.g. to inscribe a unique code or induce a variation of the device function);
An adjustment of dose, focus, CD or other patterning parameter, relevant to maximize certain key pattern parameters of the pattern on the substrate;
An adjustment of the patterning of marks, present on the patterning device.

In an embodiment of the present invention, an EBID tool is applied for providing the second patterning step. Because the EBID tool includes a SEM, it also offers to possibility to accurately assess the quality of the applied second patterning step. Further, an accurate assessment of critical features of the first patterning step can be performed as well.

In an embodiment, an e-beam lithography tool is applied for providing the first patterning step. Alternatively, in case of comparatively coarse features are to be patterned, the first patterning step can be made using an optical pattern generator or a plotter.

As illustrated above, the reticle manufacturing method according to the present invention, whereby a pattern to be provided on the reticle is patterned onto the reticle in at least two distinct patterning steps, enables a more effective and efficient use of available patterning tools. The method also enables to anticipate on a wish to customize the pattern on a reticle. By subdividing the desired pattern in the manner as discussed, an increased flexibility can be obtained with respect to customising mask patterns and a reduced manufacturing time. Overall costs for generating a mask with a particular pattern may be reduced as well.

It should be pointed out that the two step generation of the desired pattern according to the present invention is unrelated to the application of amendments made to generated patterns in order to fix defects in the patterns. It is acknowledged that the repair of defects of reticles can e.g. be performed using e-beam tool. However, the processes as performed by these tool do not enhance or modify the functionality of the pattern.

In an embodiment, the present invention provides a reticle for us in a lithographic apparatus, the reticle being manufactured according to the manufacturing method according to the invention. In an embodiment, the reticle manufacture is a reticle for use in an EUV lithographic apparatus. The reticle as manufactured may also be a reticle for use in a DUV lithographic apparatus. In an embodiment, the present invention provides in a system for providing a predetermined pattern on a reticle. In an embodiment, such a system comprises a first patterning tool configured to pattern a reticle, e.g. a reticle blank, with a first pattern. The system may further comprises a second pattern generation tool for patterning the reticle with a second pattern, whereby the combined first and second pattern results in a pattern having a desired functionality.

Alternatively, the system may comprise a pattern generation tool configured to sequentially apply the first and second pattern. In such embodiment, the system may e.g. be configured to output the reticle provided with the first pattern for evaluation during a process set up in a lithographic apparatus. Based on the outcome of the evaluation, requirements for the second pattern may be determined, the actual required layout of the second pattern may be determined and the reticle may be supplied back to the system for being patterned with the second pattern.

In an embodiment, the present invention provides in a lithographic apparatus that comprises a pattern generation tool. In an embodiment, the pattern generation tool is configured to:
receive a reticle having a first pattern, the first pattern representing a first functionality of an integrated circuit; and
pattern the reticle having the first pattern with a second pattern the combined first and second pattern having a predetermined functionality.

As such, in an embodiment of the present invention, a lithographic apparatus is provided which is capable of receiving a reticle which has a pattern on it, e.g. a basic or generic circuit design, and which is capable or adjusting or completing the pattern by patterning a second pattern on it, e.g. based on a customer requirement. Such a lithographic apparatus mag e.g. further comprise:

an illumination system configured to condition a radiation beam;
a support constructed to support the reticle, the reticle being capable of imparting the radiation beam with a pattern in its cross-section to form a patterned radiation beam;
a substrate table constructed to hold a substrate; and
a projection system configured to project the patterned radiation beam onto a target portion of the substrate.

In an embodiment, the pattern generation tool as provided in the lithographic apparatus according to the present invention is an EBID tool, as discussed above.

According to a second aspect of the present invention, there are provided methods and apparatuses or tools that enable a more accurate inspection or assessment of processes performed during the manufacturing of semiconductor devices, e.g. processes as performed by lithographic apparatus.

Typically, a manufacturing process of a semiconductor device involves a large number of processing steps, e.g. including patterning steps, etching steps, developing steps, etc. Inspection tools may be applied to assess the accuracy of each of these process steps. As such, inspection tools may be used to inspect dimensions of structures that were patterned by a lithographic apparatus or to inspect an alignment of structures in two consecutive layers of the semiconductor devices.

Inspection tools may also be applied for monitoring the performance of a lithographic apparatus over time, in order to e.g. detect any drift of a process parameter as applied. In such an arrangement, the measurements as performed can be used in a feedback loop. As an example, it has been known that the applied focus in a lithographic apparatus may vary over time or deviate from a desired focus set point; i.e. the applied focus may drift over time. Using an inspection tool, one may e.g. determine the focus as applied and providing this information to the lithographic apparatus as feedback, thus enabling the lithographic apparatus to correct the focus & correct the focal drifts. As will be understood, in order to accurately determine such a focal drift, accurate knowledge of the focus over time is required.

Typically, the measurements as performed by inspection tools may suffer from unwanted noise and interference, which can set a limit to the attainable accuracy, precision and sensitivity of the performed measurements. Examples of noise may e.g. be so called shot noise in a radiation source applied in a metrology or inspection tool or stage variations. Examples of interference may e.g. include variations in other parameters than those that are being measured, e.g. layer heights, material properties; i.e. local variations (such as line edge roughness) which may disturb a measurement of a more global fingerprint. As such, due to this noise and interference, the trustworthiness or accuracy of the measurements may not be sufficient to detects any trends in the lithographic apparatus and processes applied, such as focal drift. It would therefore the advantageous to increase the accuracy or precision of measurements as performed by inspection tools as e.g. used to inspect objects such as substrates.

In accordance with a second aspect of the present invention, a method is proposed that enables to determine more accurately a characteristic of a pattern as e.g. provided on a substrate.

FIG. 7 schematically shows a flow-chart of such method of determining a characteristic of a pattern according to the present invention.

The pattern characteristics as determined using the method according to the invention may e.g. include the determination of an applied focus or an applied dose during the patterning or exposing of the substrate or substrates. Alternatively or in addition, such a characteristic may e.g. be a geometric characteristic of the pattern. Examples of such characteristics may e.g. include Edge Placement Error (EPE), critical dimension (CD), overlay error (OVL), side wall angle (SWA), line edge roughness (LER), line width roughness (LWR).

In order to enable a more accurate determination of the required or desired characteristic of the pattern or patterns, the method according to the invention makes use, or relies on, knowledge of a process parameter variation occurring during the patterning process, also referred to as the exposure process, of the pattern or patterns. In particular, the method of determining a particular characteristic of a pattern according to the present invention makes use of data associated with one or more substrates comprising a plurality of target portions onto which a respective plurality of patterns is provided, whereby the plurality of patterns are formed by a lithographic process characterized by a known variation of at least one process parameter with respect to a nominal value.

As such, the method according to the present invention involves a first step 710 of receiving data associated with one or more substrates comprising a plurality of target portions onto which a respective plurality of patterns is provided, whereby the plurality of patterns are formed by a lithographic process characterized by a known variation of at least one process parameter with respect to a nominal value.

In an embodiment, such data may e.g. be obtained by measuring the required characteristic of the plurality of patterns using an inspection tool, e.g. an optical inspection tool or an electron beam inspection tool. Alternatively, the data may correspond to measurement data or measurements of a further or associated characteristic of the plurality of patterns.

In a second step 720, the method of determining a characteristic of a pattern comprises determining, from the data, a measurement set comprising a plurality of measurements of the respective plurality of patterns. In an embodiment, the data as received in step 710 comprises, for each of the plurality of patterns, a measurement of the required characteristic or a measurement of a further or associated characteristic. Depending on the characteristic one wishes to determine, it may be possible to measure such a characteristic directly or not. In step 720, the plurality of measurements are grouped or combined into a measurement set.

In a third step 730, the method of determining a characteristic of a pattern comprises filtering the measurement set, based on the known process parameter variation. As already indicated above, measurements as performed by inspection tools or the like may be affected by noise or interference, causing an uncertainty with respect to the accuracy or reliability of the measurements. As such, when a plurality of measurements, e.g. measurements of a particular characteristic of the plurality of patterns, are grouped in a measurement set, e.g. resulting in an array or sequence of measurement values, variations may be observed. Such variations may e.g. be caused by actual undesired process variations which have occurred during the patterning of the plurality of patterns, e.g. a focal drift or a drift of the applied dose of radiation. A second source of the variations observed in the measurement set are the aforementioned noise or interference, which may e.g. cause that the process drift may be difficult to detect.

In the measurement set as obtained by a method according to the second aspect of the present invention, there is also a third source of variations; in accordance with the second aspect of the present invention, a plurality of patterns that are to be examined or inspected are patterned by means of a lithographic process, whereby a known process parameter variation is applied during the patterning of the plurality of patterns.

In an embodiment, such a known process parameter variation may e.g. be a deliberate modulation of a process parameter, e.g. a focus setting or radiation dosage, applied during the patterning of the plurality of patterns.

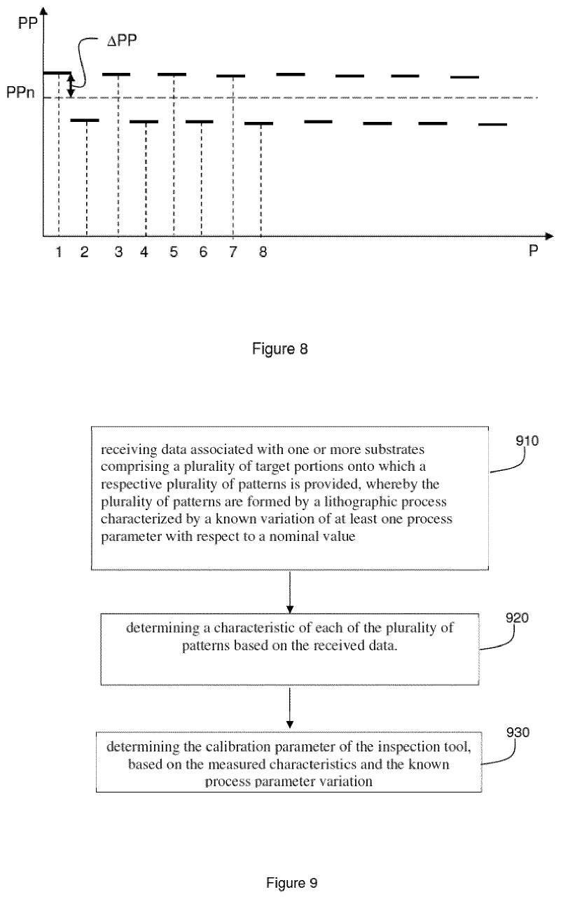

The application of such a known process parameter variation is schematically illustrated in FIG. 8. FIG. 8 schematically shows a set point of a process parameter PP as applied during the patterning process of a plurality of patterns P. In the embodiment as shown, a comparatively small offset ΔPP is alternatingly applied to the plurality of patterns P that is patterned. In particular, PP1 represent the value of the process parameter PP as applied during the pattering of patterns 1, 3, 5, etc. of the plurality of patterns P, whereas PP2 represent the value of the process parameter PP as applied during the pattering of pattern 2, 4, 6, 8, etc. of the plurality of patterns P, and so on. In FIG. 8, the dotted line represents the nominal value PPn of the applied process parameter. In the embodiment as shown, the known process parameter variation thus corresponds to a set point variation of the process parameter.

It should be pointed out that, within the meaning of the present invention, a known process parameter variation does not require that one knows the exact value of the process parameter as applied. It is sufficient to know that, during the patterning of the plurality of patterns, a particular variation to a process parameter has been applied or implemented. Such an implementation of a variation to a process parameter may, in accordance with the present invention be implemented in various manners, as will be discussed in more detail below.

In an embodiment, the applied process parameter variation may also be a pseudo-random variation. As such, there does not need to be a repetitive pattern in the applied variations. The only requirement is that the applied variations are known.

In an embodiment, as will be discussed later in more detail, the applied process parameter variation, e.g. the parameter off set ΔPP as shown in FIG. 8, may depend on the actual patterns that are applied.

The measurement set, e.g. an array of measurement values, as obtained by the method step 720 of FIG. 7 may thus contain three sources of disturbances or variations. Of these three sources, one source being the known process parameter variation. The presence of the known process parameter variation enables to provide in an effective filtering of the measurement set. In particular, because it is known that during the patterning of the plurality of patterns a particular process parameter variation is applied, a particular variation in the measurement values of the measurement set can be expected. Phrased differently, one would expect that, due to the application of the known process parameter variation, the measurement set contains a particular variation, which is in line with the applied process parameter variation.

As such, when a filtering method is applied to the measurement set which can identify particular variations or patterns in the measurement set, one may be able to distinguish between variations caused by the applied known process parameter variation and other variations. As discussed above, the other variations may e.g. be caused by noise which one would like to eliminate from the measurement set.

In an embodiment of the present invention, the filtering of the measurement set comprises fitting the measurement set to the corresponding known process parameter variation. Such a fitting may e.g. involve performing a least squares fitting between the measurement set and the known process parameter variation as applied during the patterning of the plurality of patterns. In such embodiment, weights, or coefficients are sought that provide in an optimal or optimized match between the known process parameter variation and the measurement set.

In an embodiment of the present invention, the filtering of the measurement set may involve performing an orthogonal decomposition of the measurement set into different components. Based on such a decomposition, one may remove or filter such components of decomposed measurement set that do not match or comply with the known process parameter variation.

In an embodiment, a Wiener filter may be applied for the filtering of the measurement set.

In an embodiment of the present invention, the process parameter that one would like to determine is not directly measured or available in the data. Rather, the data may contain measurements of a different parameter or characteristic, e.g. a characteristic associated or related to the process parameter one would like to determine.

As an example, the process parameter one would like to monitor may e.g. be the applied dose or the focus setting during the patterning of patterns on a plurality of substrates. In order to assess the process parameter as applied, an inspection tool is used that determines, e.g. by means of measurements performed on the patterns, a characteristic that is associated with the process parameter. In case the process parameter is e.g. the applied dose or focus setting, an associated parameter may e.g. be a CD (critical dimension) or SWA (side wall angle). Both these parameters are known to vary in dependency of the applied dose or the applied focus setting.

As such, when the relationship between a particular CD or SWA value and a corresponding dose of focus value is known, the process parameter may be monitored by assessing the associated parameter.

Deriving this relationship may be referred to as a calibration process, whereby, for a given inspection tool, one may derive how a particular measured parameter relates to another parameter, e.g. a process parameter.

In an embodiment, the present invention provides in a method of determining a calibration parameter of an inspection tool, whereby use is made of a known process parameter variation Such a method is schematically illustrated in FIG. 9. As illustrated, the calibration method according to the present invention which enables the determination of a calibration parameter of the inspection tool comprises a first step 910 of receiving data associated with one or more substrates comprising a plurality of target portions onto which a respective plurality of patterns is provided, whereby the plurality of patterns are formed by a lithographic process characterized by a known variation of at least one process parameter with respect to a nominal value. This step 910 substantially corresponds to step 710 as illustrated above, where measurement data is received relating to a plurality of patterns, whereby the patterns are created using a known process parameter variation, e.g. a dose or focus variation.

In a second step 920, the calibration method according to the present invention provides in determining a characteristic of each of the plurality of patterns based on the received data. In an embodiment, such a characteristic may e.g. be another parameter or characteristic that the process parameter which is modulated or varied during the patterning of the patterns. Such a parameter or characteristic may e.g. be a process parameter that is associated to, or has a correlation with, the process parameter that was varied during the patterning process. As an example, the characteristic that is determined may e.g. be a critical dimension or a side wall angle.

In a third step 930, the calibration method comprises the step of determining the calibration parameter of the inspection tool based on the measured characteristics and the known parameter variations. As already discussed above, by making use of the knowledge that the patterning has been performed by applying a known process parameter variation, noise components can be identified and eliminated from the measurements, enabling to determine a more accurate value of the calibration parameter.

In known calibration methods of inspection tools, use can e.g. be made of a so-called set-get experiment, whereby a particular, e.g. calibration wafer or substrate is used, which has been patterned with a plurality of focus offsets. In this respect, reference can be made to US 2012/0013875, which is incorporated by reference herein in its entirety.

In the present invention, as already indicated above, use is made of the application of a known process parameter variation, which has been applied during the patterning of a plurality of patterns.

In accordance with the present invention, there exist a variety of manners to implement this.

In an embodiment, the process parameter variation is applied to a plurality of measurement targets or metrology targets on one or more substrates or wafers. In such an embodiment, the applied process parameter variations may be comparatively large.

In an embodiment of the present invention, the process parameter variation is applied on production wafers or substrates. In such an embodiment, a process parameter variation is implemented in patterns or portions of patterns that form part of the devices that are manufactures. An important advantage of this approach is that any calibration of an inspection tool or any assessment of a process parameter is actually based on measurements that are performed on the actual product substrates or wafers, rather than on measurement or calibration wafers. As such, the conditions to arrive at e.g. a calibration parameter or calibration curve correspond to actual production conditions.

As an example of a process parameter modulation or variation that can be applied on patterns or portions of patterns that are associated with product features, a dose variation or a focus setting variation can be mentioned. In such an example, the patterning of a plurality of patterns containing product features, also referred to as production patterns, is thus performed by applying a known process parameter variation. It is submitted that when such a process parameter variation is comparatively small, this does not affect the performance of the patterning process, nor the performance of the product, e.g. integrated circuit, that is manufactured.

Examples of possible process variations that may be implemented are e.g. dose variations or focus setting variation.

As will be understood by the skilled person, an exposure process of a substrate is typically realized by projecting a plurality of radiation beam pulses onto the substrate. typically, a portion of the substrate that needs to be exposed to the radiation beam may receive several hundred pulses. Assuming e.g. that the nominal number of pulses would be 250. One may then, in order to create a plurality of patterns that include a known process parameter variation, expose a plurality of patterns on a substrate or on a plurality of substrates, with slightly varying numbers or pulses. A sequence of patterns P1-P10 may e.g. be exposed to the following number of pulses:

| P1 | P2 | P3 | P4 | P5 | P6 | P7 | P8 | P9 | P10 |
|---|---|---|---|---|---|---|---|---|---|
| 250 | 245 | 240 | 245 | 250 | 255 | 260 | 255 | 250 | 245 |

In a similar manner, a sequence of patterns may e.g. be patterned whereby a deliberate offset with respect to a nominal focal setpoint is applied. Typically, as will be understood by the skilled person, a positioning device of a lithographic apparatus which exposes the substrates is configured to position the substrate relative to the patterned beam of radiation in such manner that the surface of the substrate coincides or substantially coincides with a focal plane of the projection system. By deliberately positioning the substrate at different positions, e.g. different vertical positions in case of a projection system that emits a patterned radiation beam in a vertical direction, one may thus create a plurality of patterns which have been patterned with a known process parameter variation. In below table, focal offsets are shown, in nm for a sequence of patterns P1-P10.

| P1 | P2 | P3 | P4 | P5 | P6 | P7 | P8 | P9 | P10 |
|---|---|---|---|---|---|---|---|---|---|
| +20 | +10 | 0 | −10 | −20 | −10 | 0 | +10 | +20 | +10 |

In the above table, a focal offset of +10 may e.g. refers to a positioning of the substrate 10 nm above the nominal position, i.e. the position of the focal plane of the projection system, whereas a focal offset of −20 may e.g. refers to a positioning of the substrate 20 nm below the nominal position, i.e. the position of the focal plane of the projection system.

In case one wants to calibrate an inspection tool for measuring two parameters of interest, e.g. focal offset and applied dose, it may be possible to apply both offsets, i.e. both process parameter variations, simultaneously during the patterning. In such embodiment, it is advantageous to ensure that the patterns of both process parameter variations are not similar; they should be more or less different. The difference between both patterns of process parameter variations may e.g. be assessed via the correlation coefficient. As such, in such embodiments, the correlation coefficient should be equal to or close to zero.

As will be understood, adjusting the relative position of the substrate and the focal plane of the projection system may also be realized by adjustments in the projection system rather than adjusting the position, i.e. the position set point of the positioning device that positions the substrate.

In the above given examples, a deliberate process parameter variation has been applied, e.g. a variation in the number of pulses or a variation in the position of the substrate relative to the focal plane.

It can be pointed out that, within the meaning of the present invention, process parameter variations need not be deliberately or intentionally be applied. It may e.g. be in certain circumstances unavoidable to experience a process parameter variation. In case such a process parameter variation can be quantified and identified such that one knows, for a plurality of patterns that have been subjected to the variation, what the applied process parameter variation, this know process parameter variation may be applied as will in the present invention to provide in an improved determination of a calibration parameter of an inspection tool or to provide in a more accurate process parameter of a lithographic process as e.g. performed by a lithographic exposure apparatus. As an example, the number of pulses to which a pattern or portion of a pattern is subjected during the patterning process will typically be an integer number. It may however be impossible to ensure that each pattern or portion of a pattern receives the same number of pulses.

Referring back to the above example where a nominal number of 250 pulses is desired, it may very well be that in reality, patterns P1-P10 are exposed to the following number of pulses:

| P1 | P2 | P3 | P4 | P5 | P6 | P7 | P8 | P9 | P10 |
|---|---|---|---|---|---|---|---|---|---|
| 250 | 249 | 249 | 251 | 250 | 250 | 249 | 251 | 250 | 249 |

When the actual number of pulses as applied to each pattern can be identified, such an, albeit small, variation of a process parameter may be used as a known process parameter variation as discussed above, and may thus be used to more accurately determine a calibration parameter of e.g. an inspection tool or a process parameter.

In a similar manner, focus variations can be applied: a lithographic apparatus typically has a leveling system that can measure wafer height variations and adapt stage movements to follow those as good as possible. The residual of this process can be considered a source of focus variations of which the value can be identified and used.

It may be pointed out that the smaller the amplitude of the applied process parameter variation, the larger the number of patterns should be to arrive at the improved process parameter value or improved calibration parameter value. However, since, in an embodiment of the present invention, the process parameter variation is applied to product features rather than on a dedicated measurement or calibration wafer, it may be comparatively easy to obtain a large number of measurements or data points.

Typically, a minimal Signal-to-Noise ratio (S/N) is required for a useable measurement. A ratio commonly required is 10 (or a S/N of 20 dB).

In the proposed methods, the intentionally applied process parameter variations should be significantly smaller than the typical process variations of the parameters of interest, typically at least 3× smaller. As a consequence of the low signal of the intended variations, the noise has to be also suppressed. Noise suppression scales with the inverse of the square root of the number of measurements. Hence a typical number of measurements of (3×10)\hat{ }2=900 would be a typical number of measurement that are required in an embodiment.

In an embodiment of the present invention, the process parameter variation is realized by applying a patterning device in which different a plurality of patterns or pattern portions is provided with a known parameter variation. As an example, a pattern comprising different pattern portions which comprise marks or markings with a different width or critical dimension. As an example, a pattern provided with two or more portions consisting of gratings with a different CD may, when applied to a plurality of target portions on a substrate, be used as patterns that are patterned with a known process parameter variation. Such a patterning device may advantageously be manufactured by the manufacturing process according to the first aspect of the invention.

Starting from a nominal patterning device, i.e. provided with the actual circuit that needs to arrive on the substrate, the manufacturing method according to the present invention may be used to apply small modifications to the nominal patterning device, e.g. making small adjustments to the pattern, e.g. a thickness of a line, whereby, when afterwards the corresponding portions on the substrate are inspections, one can rely on the knowledge that a particular process parameter was varied, e.g. the particular line thickness.

In addition to relying on the fabrication process of the patterning device, it is also possible to verify the intended variations of line width on the patterning device, using an independent metrology device.

In an embodiment of the present invention, the derived process parameter, e.g. obtained by the method according to the present invention or via the improved calibration parameter, may be applied in a feedback loop of the lithographic apparatus, e.g. to compensate for process parameter drift. As the present invention enables to determine, in a more accurate manner, a process parameter, a possible drift of said process parameter may be detected in an earlier stage such that any corrective measures may be taken sooner by the lithographic apparatus.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further embodiments of the invention are disclosed in the list of numbered embodiments below:

1. Manufacturing process for a reticle having a predetermined functionality, the manufacturing method comprising:
obtaining a reticle having a first pattern, the first pattern representing a first functionality of an integrated circuit;
patterning the reticle having the first pattern with a second pattern using a pattern generating tool, the combined first and second pattern having the predetermined functionality.

2. Manufacturing process according to embodiment 1, wherein the step of patterning the reticle having the first pattern with a second pattern is preceded by:
performing a process set up of a lithographic apparatus using the reticle;
determining a desired characteristic of the reticle, based on the process set up;
determining the second pattern based on desired characteristic.

3. Manufacturing process according to embodiment 2, wherein the desired characteristic comprises a dimension of a mark on the reticle, and wherein the second pattern comprises one or more marks having the dimension.

4. Manufacturing method for a reticle, the manufacturing method comprising:
providing a reticle to a first pattern generating tool;
patterning the reticle with a first pattern;
providing the reticle having the first pattern to a second pattern generating tool;
patterning the reticle with a second pattern configured to form a combined pattern with the first pattern, wherein the combined pattern has a different functionality than the first pattern.

5. Manufacturing method according to embodiment 4, further comprising:
providing a further reticle onto which a pattern is to be provided to the first pattern generating tool;
patterning the further reticle with the first pattern;
providing the further reticle having the first pattern to the second pattern generating tool;
patterning the further reticle with a third pattern; a further combined pattern comprising the first and third pattern having a different functionality than the first pattern and than the combined pattern.

6. The manufacturing method according to embodiment 4, wherein the first pattern represents a basic circuit pattern.

7. The manufacturing method according to embodiment 4 or 5, wherein the second pattern represents a customer specific pattern or a customer specific modification of the first pattern.

8. The manufacturing method according to embodiment 5, wherein the third pattern represents a further customer specific pattern.

9. The manufacturing method according to embodiment 4, wherein the first pattern generating tool comprises an e-beam exposure system.

10. The manufacturing method according to embodiment 4, wherein the second pattern generating tool comprises an e-beam induced deposition tool.

11. The manufacturing method according to embodiment 1, wherein the first pattern comprises a plurality of alignment marks having different dimensions and wherein the second pattern comprises a plurality of alignment marks having the same dimensions.

12. The manufacturing method according to embodiment 4, wherein the second pattern is a volatile pattern.

13. The manufacturing method according to embodiment 4, wherein the second pattern is removable.

14. The manufacturing method according to embodiment 13, wherein the second pattern is removable by means of plasma cleaning using radicals.

15. A reticle manufactured according to the manufacturing process according to any of the preceding embodiments.

16. The reticle according to embodiment 15, wherein the reticle is suited for EUV lithography.

17. The reticle according to embodiment 15, wherein the reticle is suited for DUV lithography.

18. A system configured to perform the manufacturing process according to any of the embodiments 1 to 14.

19. A system for patterning a reticle with a pattern, the system comprising:
a first pattern generating tool configured to pattern the reticle with a first pattern;
a second pattern generation tool for patterning the reticle with a second pattern, whereby the combined first and second pattern forms a pattern having a desired functionality.

20. A lithographic apparatus comprising:

a pattern generation tool configured to:
receive a reticle having a first pattern, the first pattern representing a first functionality of an integrated circuit;
patterning the reticle with a second pattern configured to form a combined pattern with the first pattern, wherein the combined pattern has a predetermined functionality;
   an illumination system configured to condition a radiation beam;
   a support constructed to support the reticle, the reticle being capable of imparting the radiation beam with a pattern in its cross-section to form a patterned radiation beam;
   a substrate table constructed to hold a substrate; and
   a projection system configured to project the patterned radiation beam onto a target portion of the substrate.

21. Calibration method of an inspection tool, the calibration method comprising determining a calibration parameter of the inspection tool by:
receiving data associated with one or more substrates comprising a plurality of target portions onto which a respective plurality of patterns is provided, whereby the plurality of patterns are formed by a semiconductor manufacturing process characterized by a known variation of at least one process parameter with respect to a nominal value;
determining a characteristic of each of the plurality of patterns based on the received data; and
determining the calibration parameter of the inspection tool, based on the measured characteristics and the known process parameter variation.

22. The calibration method according to embodiment 21, wherein the step of determining the calibration parameter comprises filtering the measured characteristics based on the known process parameter variation.

23. The calibration method according to embodiment 21 or 22, wherein the known process parameter variation comprises a variation of an applied focus or exposure dose during an exposure process comprised within the semiconductor manufacturing process.

24. The calibration method according to any of the preceding embodiments, wherein the plurality of patterns comprises a respective plurality of product features of semiconductor devices.

25. The calibration method according to any of the preceding embodiments, wherein the plurality of patterns comprises a respective plurality of metrology targets.

26. The calibration method according to any of the preceding embodiments, wherein the calibration parameter comprises a calibration curve.

27. The calibration method according to embodiment 26, wherein the calibration curve represents a relationship between the measured characteristic and the process parameter.

28. The calibration method according to embodiment 27, wherein the measured characteristic comprises a critical dimension or a side wall angle.

29. The calibration method according to any of the embodiments 21 to 28, wherein the known process parameter variation comprises a set point variation of the process parameter.

30. A method of determining a characteristic of a pattern, the method comprising:
receiving data associated with one or more substrates comprising a plurality of target portions onto which a respective plurality of patterns is provided, whereby the plurality of patterns are formed by a semiconductor manufacturing process characterized by a variation of at least one process parameter with respect to a nominal value;
determining a measurement set comprising a plurality of measured characteristics of the respective plurality of patterns from that data;
filtering the measurement set based on the process parameter variation.

31. The method according to embodiment 30, further comprising the step of:
outputting the filtered measurement set.

32. The method according to embodiment 30 or 31, wherein the method is preceded by the calibration method according to any of the embodiments 21 to 29.

33. An inspection tool configured to perform the method according to any of the embodiments 30 to 32.

34. An inspection method of determining a characteristic of a pattern, the method comprising:
receiving one or more substrates comprising a plurality of target portions onto which a respective plurality of patterns is provided, whereby the plurality of patterns are formed by a semiconductor manufacturing process characterized by a variation of at least one process parameter with respect to a nominal value;
obtaining a measurement set comprising a plurality of measured characteristics of the respective plurality of patterns using an inspection tool;
filtering the measurement set based on the process parameter variation.

35. The inspection tool according to embodiment 33, wherein the inspection tool is an optical inspection tool.

36. The inspection tool according to embodiment 33, wherein the inspection tool is an electron beam inspection tool.

37. A method of patterning substrates using a semiconductor processing apparatus comprising a step of: providing one or more substrates comprising a plurality of target portions with a respective plurality of patterns using the semiconductor processing apparatus characterized in that a process parameter variation with respect to a nominal value is applied to said plurality of target portions.

38. The exposure process according to embodiment 37, wherein the plurality of patterns comprises a respective plurality of product features of semiconductor devices.

39. The exposure process according to embodiment 38, wherein the known process parameter variation is below a predetermined variation threshold.

40. The exposure process according to embodiment 39, wherein the variation threshold is selected to be smaller than an allowable process parameter variation required to pattern the plurality of patterns.

41. The exposure process according to embodiment 39 or 40 wherein the known process parameter variation is a deliberately applied process parameter variation.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1.-15. (canceled)

16. A method for manufacturing or adjusting a reticle having a predetermined functionality, the method comprising:
obtaining a reticle having a first pattern, the first pattern representing a first functionality of structures provided to a substrate using the reticle; and
patterning the reticle having the first pattern with a second pattern using a pattern generating tool, the combined first and second patterns having the predetermined functionality.

17. The method according to claim 16, wherein the patterning the reticle having the first pattern with a second pattern is preceded by:
performing a process set up of a lithographic apparatus using the reticle;
determining a desired characteristic of the reticle, based on the process set up; and
determining the second pattern based on desired characteristic.

18. The method according to claim 17, wherein the desired characteristic comprises a dimension of a mark on the reticle, and wherein the second pattern comprises one or more marks having the dimension.

19. The method according to claim 16, wherein the first pattern comprises a plurality of marks having different dimensions and wherein the combined first and second patterns comprises a plurality of marks having the same dimensions.

20. A reticle manufactured or adjusted according t the method of claim 16.

21. The reticle according to claim 20, wherein the reticle is suited for EUV lithography.

22. The reticle according to claim 20, wherein the reticle is suited for DUV lithography.

23. A system configured to perform the method according to claim 16.

24. A method for adjusting a reticle, the method comprising:
providing a reticle to a first pattern generating tool;
patterning the reticle with a first pattern;
providing the reticle having the first pattern to a second pattern generating tool; and
patterning the reticle with a second pattern configured to form a combined pattern with the first pattern,
wherein the combined pattern has a different functionality than the first pattern.

25. The method according to claim 24, further comprising:
providing a further reticle, onto which a pattern is to be provided, to the first pattern generating tool;
patterning the further reticle with the first pattern;
providing the further reticle having the first pattern to the second pattern generating tool;
patterning the further reticle with a third pattern,
wherein a further combined pattern comprising the first and third patterns has a different functionality than the first pattern and than the combined pattern.

26. The method according to claim 25, wherein the third pattern represents a customer specific pattern.

27. The method according to claim 24, wherein the first pattern represents a basic circuit pattern.

28. The method according to claim 24, wherein the second pattern represents a customer specific pattern or a customer specific modification of the first pattern.

29. The method according to claim 24, wherein the first pattern generating tool comprises an electron beam exposure system.

30. The method according to claim 24, wherein the second pattern generating tool comprises an electron beam induced deposition tool.

31. The method according to claim 24, wherein the second pattern is a volatile pattern.

32. The method according to claim 24, wherein the second pattern is removable.

33. The method according to claim 32, wherein the second pattern is removable by means of plasma cleaning using radicals.

34. A system for patterning a reticle with a pattern, the system comprising:
a first pattern generating tool configured to pattern the reticle with a first pattern; and
a second pattern generation tool configured to pattern the reticle with a second pattern,
wherein the combined first and second patterns form a pattern having a desired functionality.

35. A lithographic apparatus comprising:
a pattern generation tool configured to:
receive a reticle having a first pattern, the first pattern representing a first functionality of an integrated circuit; and
pattern the reticle with a second pattern configured to form a combined pattern with the first pattern, wherein the combined pattern has a predetermined functionality;
a support constructed to support the reticle, the reticle being capable of imparting a radiation beam with a pattern in its cross-section to form a patterned radiation beam;
a substrate table constructed to hold a substrate; and
a projection system configured to project the patterned radiation beam onto a target portion of the substrate.
